(19) United States
(12) Patent Application Publication
(10) Pub. No.: US 2012/0070780 A1
(43) Pub. Date: Mar. 22, 2012

(54) PHOTOSENSITIVE RESIN COMPOSITION, DRY FILM SOLDER RESIST, AND CIRCUIT BOARD

(75) Inventors: Bo-Yun CHOI, Daejeon (KR); Byung-Ju CHOI, Daejeon (KR); Woo-Jae JEONG, Daejeon (KR); Kwang-Joo LEE, Daejeon (KR); Min-Su JEONG, Daejeon (KR)

(73) Assignee: LG CHEM, LTD., Seoul (KR)

(21) Appl. No.: 13/235,071

(22) Filed: Sep. 16, 2011

(30) Foreign Application Priority Data
Sep. 16, 2010 (KR) 10-2010-0091084

(51) Int. Cl. G03F 7/032

(52) U.S. Cl. 430/280.1; 430/281.1

(57) ABSTRACT

The present invention relates to a photosensitive resin composition including an acid modified oligomer, a photopolymerizable monomer, a thermosetting binder resin, a photoinitiator, and a thioxanthone compound, a dry film solder resist obtained from the resin composition, and a circuit board including the dry film solder resist.

### CROSS REFERENCE TO RELATED APPLICATIONS

This application claims priority under 35 U.S.C. §119 to Korean Patent Application No. 10-2010-0091084 filed Sep. 16, 2010, which is incorporated herein in its entirety.

### TECHNICAL FIELD

The present invention relates to a photosensitive resin composition, a dry film solder resist, and a circuit board, and it is directed to a photosensitive resin composition capable of providing a photosensitive material superior in photocuring characteristics, plating resistance, mechanical properties, and heat resistance, a dry film solder resist, and a circuit board including the dry film solder resist.

### BACKGROUND OF THE INVENTION

With various electronic devices becoming smaller and lighter, photosensitive protective films capable of producing fine hole patterns are used in a printed circuit board (PCB), a semiconductor package board, a flexible printed circuit board (FPCB), and the like.

Protective films, also referred to as “solder resists,” are typically required to have some characteristics such as developability, high resolution, developability electrical insulatability, solder heat resistance, and gold plating resistance. Besides these characteristics, the solder resist for use in a package board should show a crack-resistance property in a temperature cycle test (TCT) conducted at a temperature of 55° C. to 125° C. and good results in a highly accelerated stress test (HAST) for microwiring.

In recent years, dry film solder resists (DFSRs) have received much attention due to their good performances in terms of uniformity of the film thickness, surface smoothness, and thin-film forming ability. Using such a dry film solder resist enables one to simplify a process for forming a resist and to reduce the amount of solvent discharged in the process of the resist formation.

Photocuring and thermocuring processes can enhance many properties of the protective film for the printed circuit board, such as thermal stability, mechanical properties, chemical resistance, and moisture absorbing property. In this regard, initial photocuring characteristics are crucial because the films are photocured and developed to form a pattern before being subject to thermocuring and final photocuring (post cure) processes. When the initial photocuring is insufficient, not only does the film suffer deterioration in mechanical and thermal properties but also its reliability can be adversely affected. In addition, insufficient initial photocuring can cause whitening in a plating process.

Determination of the types and amounts of a photo-initiator and the light intensity is very important for improving the initial photocuring characteristics. However, as the light intensity increases and thus the film is further photocured, the plating property can be improved, but at the same time, the patterning ability can deteriorate and the high intensity of light may lower the processability. Therefore, there has been an urgent need to develop a composition for a solder resist that can be photocured sufficiently without causing deterioration in the processability, thereby making it possible to enhance both the patterning ability and the plating properties at the same time.

### DETAILED DESCRIPTION OF THE INVENTION

### Technical Objectives

The present invention provides a photosensitive resin composition capable of providing a photosensitive material that is superior in photocuring characteristics, plating resistance, mechanical properties, and heat resistance.

Further, the present invention provides a dry film solder resist that is superior in photocuring characteristics, plating resistance, mechanical properties, and heat resistance.

Further, the present invention provides a circuit board including the dry film solder resist.

### Technical Solution

The present invention provides a photosensitive resin composition including an acid modified oligomer, a photopolymerizable monomer, a thermosetting binder resin, a photoinitiator, and a thioxanthone compound.

The present invention also provides a dry film solder resist prepared from the photosensitive resin composition.

The present invention also provides a circuit board including the dry film solder resist.

Hereinafter, the photosensitive resin composition, the dry film solder resist, and the circuit board in accordance with the specific embodiments of the present invention will be explained in further detail.

According to an embodiment of the present invention, a photosensitive resin composition including an acid modified oligomer, a photopolymerizable monomer, a thermosetting binder resin, a photoinitiator, and a thioxanthone compound is provided.

To complete the present invention, the present inventors discovered experimentally that a photosensitive material that is superior in photocuring characteristics, plating resistance, mechanical properties, and heat resistance can be obtained from a photosensitive resin composition wherein a thioxanthone compound is utilized along with a photoinitiator.

In particular, when being photocured and thermally cured, the photosensitive resin composition of the present invention provides a dry film solder resist that is usable as a protective film for a circuit board. The resultant dry film solder resist has the thioxanthone compound, preferably 2-isopropyl thioxanthone, 4-isopropyl thioxanthone, or a mixture thereof remaining therein so that it is allowed to exhibit excellent initial photocuring characteristics and thus to render the crosslinked structure formed by the photocuring or thermocuring reaction to be denser, thereby improving mechanical properties such as heat resistance and durability.

Also, in the photosensitive resin composition according to an embodiment of the present invention, both the thioxanthone compound and the photoinitiator are added to the acid modified oligomer, the photopolymerizable monomer, and the thermosetting binder resin together to produce a dry film solder resist or a protective film for a circuit board that has a crosslinked structure resulting from the photocuring and the thermocuring. This can differentiate the photosensitive resin composition of the present invention from any processing chemicals or compositions providing a photosensitive layer or film that should be removed (or peeled off) in the preparation process of a semiconductor or a display.

The thioxanthone compound can include a compound of Chemical Formula 1 as follows.

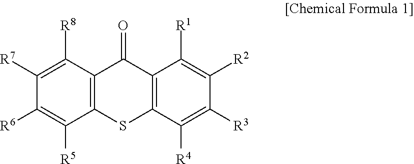

In Chemical Formula 1, each of R¹ to R⁸ can be the same or different from one another, and are hydrogen, a C1 to C5 alkyl group, a C1 to C5 alkylene group, or a C1 to C5 alkenyl group.

As preferred examples for the thioxanthone compound, mention may be made of 2-isopropyl thioxanthone, 4-isopropyl thioxanthone, or a mixture thereof. Since a bulky isopropyl group rather than a linear alkyl group having no more than 3 carbon atoms is introduced into the thioxanthone compound, the dry film solder resist or the protective film for a circuit board prepared from the photosensitive resin composition can have better mechanical properties such as heat resistance and durability.

In particular, using a mixture of 2-isopropyl thioxanthone and 4-isopropyl thioxanthone, more preferably a mixture of 2-isopropyl thioxanthone and 4-isopropyl thioxanthone, at a ratio of 1:2 to 2:1 can make a great improvement on the initial photocuring characteristics including plating resistance.

The thioxanthone compound can be included along with the photoinitiator in an amount of 1% to 20% by weight, preferably 2% to 15% by weight, and most preferably 3% to 10% by weight based on the total weight of the photosensitive resin composition.

When the photoinitiator and the thioxanthone compound are included in an amount of 1% to 20% by weight based on the total weight of the photosensitive resin composition, the protective film for a printed circuit board shows optimized properties such as heat resistance while including them in a minimum amount for inducing a photocuring reaction.

The thioxanthone compound can be included in an amount of 3 to 70 parts by weight, preferably 5 to 50 parts by weight, and more preferably 10 to 45 parts by weight with respect to 100 parts by weight of the photoinitiator. Using the thioxanthone compound and the photoinitiator within the foregoing content range makes it possible to obtain a film for a printed circuit board that shows excellent initial photocuring characteristics including plating resistance and heat resistance reliability even at any level of light intensity.

According to the above embodiments of the present invention, the photosensitive resin composition includes the acid modified oligomer, the photopolymerizable monomer, the thermosetting binder resin, the photoinitiator, and the thioxanthone compound, and if necessary, it can further include a thermocuring catalyst, a thermocuring agent, a filler, a pigment, a leveling agent, a dispersant, or a solvent.

Acid Modified Oligomers

The acid-modified oligomer is an oligomer including a carboxyl group and a vinyl group, the main chain of which can be typically novolac epoxy or polyurethane. The carboxyl group makes the oligomer soluble in an alkaline solution, enabling an alkaline developing process, and participates in thermal curing with an epoxy group as well. The vinyl group can be photo-polymerized via a radical reaction.

As the acid-modified oligomer, one can use a compound obtained by polymerization of a polymerizable monomer having a carboxyl group and methyl methacrylate, methyl acrylate, or ethyl acrylate.

Specifically, the compounds listed hereinbelow may be used as the acid-modified oligomer. It is possible to use at least one selected from the group consisting of:

(1) a carboxyl group-containing resin prepared from the copolymerization of an unsaturated carboxylic acid compound (a) such as (meth)acrylic acid, and a compound having an unsaturated double bond (b) such as styrene, α-methyl styrene, a lower alkyl(meth)acrylate, and isobutylene;

(2) a copolymer of an unsaturated carboxylic acid (a) and an unsaturated double bond-containing compound (b), a part of the copolymer having an ethylenic unsaturated group such as a vinyl group, an allyl group, and a (meth)acryloyl group, and a reactive group such as an epoxy group and an acid chloride group (e.g., a photosensitive, carboxyl group-containing resin prepared by conducting a reaction with glycidyl(meth)acrylate and adding an ethylenic unsaturated group as a pendent thereto);

(3) a photosensitive, carboxyl group-containing resin prepared by reacting a copolymer of a compound (c) having an epoxy group and an unsaturated double bond (e.g., glycidyl(meth)acrylate, and α-methylglycidyl(meth)acrylate) and an unsaturated double bond-containing compound (b) with an unsaturated carboxylic acid (a) and then reacting the secondary hydroxyl group as generated with a saturated or unsaturated polybasic anhydride (d) such as phthalic anhydride, tetrahydrophthalic anhydride, and hexahydrophthalic anhydride;

(4) a photosensitive, carboxyl group-containing resin prepared by reacting a compound (f) having one hydroxyl group and at least one ethylenic unsaturated double bond (e.g., hydroxyalkyl(meth)acrylate) with a copolymer of an acid anhydride having an unsaturated double bond (e) such as maleic anhydride and itaconic anhydride and a compound (b) having an unsaturated double bond;

(5) a photosensitive, carboxyl group-containing compound prepared by subjecting an epoxy group of a multifunctional epoxy compound having at least two epoxy groups in a molecule (g) or a multifunctional epoxy resin obtained by further epoxydizing a hydroxyl group of the multifunctional epoxy compound with epichlorohydrin to an esterification reaction (e.g., a complete esterification or a partial esterification, and preferably a complete esterification) with a carboxylic group of an unsaturated monocarboxylic acid (h) such as (meth)acrylic acid, and subjecting the hydroxyl group as generated to a reaction with a saturated or unsaturated polybasic acid anhydride (d);

(6) a carboxyl group-containing resin prepared by subjecting an epoxy group of a copolymer of a compound having an unsaturated double bond (b) and glycidyl(meth)acrylate to a reaction with an organic acid having one carboxylic acid group per molecule and not having any ethylenic unsaturated bond (i) (e.g., a C2 to C17 alkyl carboxylic acid, an aromatic group-containing alkyl carboxylic acid, or the like) and then subjecting the secondary hydroxyl group generated therefrom to a reaction with a saturated or unsaturated polybasic anhydride (d);

(7) a carboxyl group-containing urethane resin prepared by a polyaddition reaction of diisocyanate compounds (j) such as an aliphatic diisocyanate, a branched aliphatic diisocyanate, a cycloaliphatic diisocyanate, or an aromatic diisocyanate with a carboxyl group-containing dialcohol compound (k) such as dimethylol propionic acid or dimethylol butanic acid and a diol compound (m) such as polycarbonate polyols, bisphenol A alkylene oxide adduct diols, or a compound having a phenolic hydroxyl group and an alcoholic hydroxyl group;

(8) a photosensitive, carboxyl group-containing urethane resin prepared by a polyaddition reaction of a diisocyanate compound (j), a (meth)acrylate of a bifunctional epoxy resin such as a bisphenol A epoxy resin, a hydrogenated bisphenol A epoxy resin, a brominated bisphenol A epoxy resin, a bisphenol F epoxy resin, a bisphenol S epoxy resin, a bixylenol epoxy resin, and a biphenol epoxy resin, or its partially-modified product with an acid anhydride, a carboxyl group-containing dialcohol compound (k), and a diol compound (m);

(9) a carboxyl group-containing urethane resin with an unsaturated double bond as introduced at its end prepared by adding a compound having one hydroxyl group and at least one ethylenic double bond (f) such as hydroxyalkyl(meth)acrylate during synthesis of the resin (7) or the resin (8);

(10) a carboxyl group-containing urethane resin prepared by adding a compound having one isocyanate group and at least one (meth)acryloyl group in a molecule such as an equimolar reaction product of isophorone diisocyanate and pentaerythrytol triacrylate during synthesis of the resin (7) or the resin (8) and introducing a (meth)acrylic group into the resulting product at any of its ends;

(11) a photosensitive, carboxyl group-containing resin prepared by subjecting a multifunctional oxetane compound with at least two oxetane rings in the molecule as described below to a reaction with an unsaturated monocarboxylic acid (h) and then reacting a primary hydroxyl group of the modified oxetane compound thus obtained with a saturated or unsaturated polybasic acid anhydride (d);

(12) a carboxyl group-containing polyester resin prepared by reacting a bifunctional epoxy resin or bifunctional oxetane resin as described below with a dicarboxylic acid compound, and adding to the primary hydroxyl group thus generated a saturated or unsaturated polybasic acid anhydride;

(13) a photosensitive, carboxyl group-containing resin prepared by introducing an unsaturated double bond into a reaction product of a bisepoxy compound and a bisphenol compound, and subsequently reacting the resulting product with a saturated or unsaturated polybasic acid anhydride (d); and

(14) a photosensitive, carboxyl group-containing resin prepared by reacting an unsaturated monocarboxylic acid (h) with a reaction product of a novolac phenol resin with an alkylene oxide such as ethylene oxide, propylene oxide, butylene oxide, trimethylene oxide, tetrahydrofurane, or tetrahydropyrane and/or a cyclic carbonate compound such as ethylene carbonate, propylene carbonate, butylene carbonate, and 2,3-carbonate propyl methacrylate, and subsequently reacting the resulting product thus obtained with a saturated or unsaturated polybasic acid anhydride (d).

What is preferable among the carboxyl group-containing resins as described above is the resins as set forth in (7) to (10), wherein the isocyanate compound (including a diisocyanate compound) as used in their synthesis is a diisocyanate compound with no benzene ring. It is also preferred that the multifunctional or bifunctional epoxy resin as utilized in the synthesis of the resins as set forth in (5), (8), and (12) is a linear structured compound having a bisphenol A skeleton, a bisphenol F skeleton, a biphenyl skeleton, or a bixylenol skeleton and its hydrogenated compound. When the foregoing compounds are used as the acid modified oligomer, the resulting product shows an excellent level of flexibility.

The resins as set forth in (7) to (10) and their modified products such as the resin as set forth in (12) have a urethane group in their main chains so that they can be preferably used due to their excellent flexural properties. In addition, because the resins except for what are set forth in (1), (6), (7), (11), and (12) have a photosensitive group (i.e., an unsaturated double bond that can be polymerized via a radical reaction) in the molecules, they are preferred in light of photocuring characteristics. One can also use ZAR-2000, marketed by Nippon Kayaku Co. Ltd.

The amount of the acid modified oligomer ranges preferably from 15% to 75% by weight, and more preferably 25% to 65% by weight, based on the total weight of the photosensitive resin composition. When its amount is less than 15% by weight, the film strength deteriorates. When its amount is more than 75% by weight, the composition can be developed in excess and the uniformity of the coating can be worsened.

The acid value of the acid modified oligomer is preferably 40 to 120 mgKOH/g. An acid value below 40 mg KOH/g can make the alkaline developing process more difficult. When the acid value is above 120 mg KOH/g, the developing solution may dissolve even the irradiated portion, thereby overly attenuating the lines or peeling out the whole film whether being irradiated or not, and thus no desired pattern of the resist may be obtained.

Photopolymerizable Monomer

As the photopolymerizable monomer, one can use any compound that has at least two multifunctional vinyl groups so as to serve as a crosslinker during photopolymerization, and preferably a multifunctional epoxy(meth)acrylate. Unless defined otherwise herein, the term “(meth)acrylate” refers to an acrylate or a methacrylate, and the term “(meth)acryloyl group” refers to an acryloyl group or a methacryloyl group.

The photopolymerizable monomer enables the photosensitive resin composition to exhibit proper photo-curability, to have suitable viscosity for each of different coating methods, or to possess appropriate solubility for an aqueous alkaline solution.

Specific examples of the photopolymerizable monomer useful in the present invention include: a hydroxyl group-containing acrylate such as 2-hydroxyethyl(meth)acrylate, 2-hydroxypropyl(meth)acrylate, pentaerythritol tri(meth)acrylate, dipentaerythritol penta(meth)acrylate, and the like; a water soluble (meth)acrylate compound such as polyethylene glycol di(meth)acrylate, polypropylene glycol di(meth)acrylate, and the like; a multifunctional polyester(meth)acrylate compound of a polyhydric alcohol such as trimethylol propane tri(meth)acrylate, pentaerythritol tetra(meth)acrylate, dipentaerythritol hexa(meth)acrylate, and the like; an (meth)acrylate compound of an ethylene oxide adduct of multifunctional alcohols such as trimethylol propane, hydrogenated bisphenol A, and the like; a (meth)acrylate compound of an ethylene oxide adduct of polyhydric phenol such as bisphenol A, biphenyl, and the like; a (meth)acrylate compound of a propylene oxide adduct of multifunctional alcohols such as trimethylol propane, hydrogenated bisphenol A, and the like; a (meth)acrylate compound of an propylene oxide adduct s of polyhydric phenol such as bisphenol A, biphenyl, and the like; a multifunctional or monofunctional polyurethane(meth)acrylate which is an isocyanate-modified compounds of said hydroxyl group-containing (meth)acrylate compound; an epoxy(meth)acrylate compound which is a (meth)acrylic acid adduct of bisphenol A diglycidyl ether, hydrogenated bisphenol A diglycidyl ether, or phenol novolac epoxy resin; and a caprolactone-modified (meth)acrylate compound such as caprolactone-modified ditrimethylol propane tetra(meth)acrylate, ε-caprolactone-modified dipentaerythritol(meth)acrylate, caprolactone-modified hydroxypivalic acid neopentyl glycol ester di(meth)acrylate, and the like; and a mixture of at least two of the foregoing compounds.

In particular, what can be more preferably used in the photosensitive resin composition as the photopolymerizable monomer includes a multifunctional (meth)acrylate compound with at least two (meth)acryloyl groups per molecule, specific examples of which include, but are not limited to, pentaerythritol tri(meth)acrylate, trimethylol propane tri(meth)acrylate, dipentaerythritol hexa(meth)acrylate, and caprolactone-modified ditrimethylol propane tetra(meth)acrylate. As the photopolymerizable monomer, one can also use DPEA-12, commercially available from Nippon Kayaku, Co. Ltd.

It is preferred that the content of the photopolymerizable monomer is from 5% to 40% by weight, based on the total weight of the photosensitive resin composition. Using the photopolymerizable monomer in an amount of less than 5% by weight may lead to insufficient photocuring, while using it in an amount of more than 40% by weight may disadvantageously worsen the film-drying characteristics and the film properties.

Photoinitiator

The photoinitiator plays a role of initiating photocuring via a radical reaction. The photoinitiator useful in the present invention includes any one typically used in a photosensitive resin composition without particular limitations. For example, the photoinitiator that can be used includes a benzoin compound, an acetophenone compound, an anthraquinone compound, a thioxanthone compound, a ketal compound, a benzophenone compound, an α-aminoacetophenone compound, an acylphosphine oxide compound, an oxime ester compound, a biimidazole compound, a triazine compound, and a mixture thereof.

As more specific examples for the photoinitiator, mention may be made of a benzoin compound such as benzoin, benzoin methyl ether, and benzoin ethyl ether, and its alkyl ether compound; an acetophenone compound such as acetophenone, 2,2-dimethoxy-2-phenylacetophenone, 1,1-dichloroacetophenone, 2,2-diethoxy-2-phenylacetophenone, and 4-(1-t-butyldioxy-1-methylethyl)acetophenone; an anthraquinone compound such as 2-methylanthraquinone, 2-amylanthraquinone, 2-t-butylanthraquinone, 1-chloroanthraquinone, and 2-ethylanthraquinone; a thioxanthone compound such as 2,4-dimethylthioxanthone, 2-4-diisopropylthioxanthone, and 2-chloro thioxanthone; a ketal compound such as acetophenone dimethyl ketal and benzyl dimethyl ketal; a benzophenone compound such as benzophenone, 4-(1-t-butyldioxy-1-methylethyl)benzophenone, and 3,3′,4,4′-tetrakis(t-butyl dioxycarbonyl)benzophenone.

In addition, one can preferably use an α-aminoacetophenone compound such as 2-methyl-1-[4-(methylthio)phenyl]-2-morpholinopropanone-1,2-benzyl-2-dimethylamino-1-(4-morpholinophenyl)-butan-1-one, 2-(dimethylamino)-2-[(4-methylphenyl)methyl]-1-[4-(4-morpholinyl)phenyl]-1-butanone, and N,N-dimethylaminoacetophenone (Irgacure® 907, Irgacure® 369, Irgacure® 379, and the like as commercially available from Ciba Specialty Chemicals Co., Ltd. (now Ciba Japan Co., Ltd.)); an acylphosphine oxide compound such as 2,4,6-trimethylbenzoyldiphenylphosphine oxide, bis(2,4,6-trimethylbenzoyl)-phenylphosphine oxide, and bis(2,6-dimethoxybenzoyl)-2,4,4-trimethyl-pentylphosphine oxide (Lucilin® commercially available from BASF Co., Irgacure® 819 from Ciba Specialty Chemicals Co., Ltd., and the like).

It is also possible to use an oxime ester compound as the photoinitiator. As specific examples of the oxime ester compounds, mention may be made of 2-(acetyloxyiminomethyl)thioxanthene-9-one, (1,2-octanedione, 1-[4-(phenylthio)phenyl]-, 2-(o-benzoyloxime)), (ethanone, 1-[9-ethyl-6-(2-methylbenzoyl)-9H-carbazole-3-yl]-, 1-(o-acetyloxime)). As commercially available products, mention may be made of GGI-325, Irgacure OXE01 and Irgacure OXE02 from Ciba Specialty Chemicals Co., Ltd., N-199 from ADEKA Co. Ltd., and Darocur TPO from Ciba Specialty Chemicals Co., Ltd.

The photosensitive resin composition can include the photoinitiator in an amount of 0.1% to 10% by weight, and preferably 0.5% to 5% by weight. When the content of the photoinitiator is too small, the radical polymerization for the photocuring may not occur sufficiently. An excess amount of the photoinitiator may lead to worsening the developability of the dry film prepared from the composition.

Thermosetting Binder Resin

The thermosetting binder resin can be any thermosetting resin including at least one functional group selected from the group consisting of an epoxy group, an oxetanyl group, a cyclic ether group, and a cyclic thioether group. Such a thermosetting binder resin can be thermally cured by an acid modified oligomer or an epoxy curing agent that can be further added to the photosensitive resin composition.

The thermosetting binder resin as used should have a softening point of 70° C. to 100° C. in order to minimize bumpy lamination. Using a thermosetting binder resin with a lower softening point may cause an increase in the tackiness of the film, while using a thermosetting binder resin with a higher softening point can make the photosensitive resin composition difficult to flow.

As preferred examples for the thermosetting binder resin, mention may be made of a thermosetting resin having at least two cyclic ether groups and/or cyclic thioether groups (hereinafter referred to as “cyclic (thio)ether”). What is preferred among them is a bifunctional epoxy resin, and other than that, one can use a diisocyanate compound or its bifunctional block isocyanate compound.

The thermosetting binder resin having at least two cyclic (thio)ether groups can be a compound having at least two functional groups selected from the group consisting of 3-, 4-, and 5-membered cyclic ether groups and 3-, 4-, 5-membered cyclic thioether groups.

Specifically, the thermosetting binder resin can be a multifunctional epoxy resin having at least two epoxy groups, a multifunctional oxetane resin having at least two oxetanyl groups, or an episulfide resin having at least two thioether groups.

As specific examples of the multifunctional epoxy resin, mention may be made of a bisphenol A epoxy resin, a hydrogenated bisphenol A epoxy resin, a brominated bisphenol A epoxy resin, a bisphenol F epoxy resin, a bisphenol S epoxy resin, a novolac epoxy resin, a phenol novolac epoxy resin, a cresol novolac epoxy resin, an N-glycidyl epoxy resin, a novolac epoxy resin of bisphenol A, a bixylenol epoxy resin, a biphenol epoxy resin, a chelate epoxy resin, a glyoxal epoxy resin, an amino group-containing epoxy resin, a rubber modified epoxy resin, a dicyclopentadiene phenolic epoxy resin, a diglycidylphthalate resin, a heterocyclic epoxy resin, a tetraglycidyl xylenoyl ethane resin, a silicone modified epoxy resin, and an ε-caprolactone modified epoxy resin. In addition, for the purpose of imparting a flame retardant property, one may further introduce a phosphorus element into the above-mentioned multifunctional epoxy resins. Such a multifunctional epoxy resin can increase the adhesion of the cured film, solder heat resistance, or electroless plating resistance for the thermal curing.

As specific examples of the multifunctional oxetane resin, mention may be made of multifunctional oxetane compounds such as bis([3-methyl-3-oxetanylmethoxy]methyl)ether, bis([3-ethyl-3-oxetanylmethoxy]methyl)ether, 1,4-bis([3-methyl-3-oxetanylmethoxy]methyl)benzene, 1,4-bis([3-ethyl-3-oxetanylmethoxy]methyl)benzene, (3-methyl-3-oxetanyl)methylacrylate, (3-ethyl-3-oxetanyl)methylacrylate, (3-methyl-3-oxetanyl)methylmethacrylate, (3-ethyl-3-oxetanyl)methylmethacrylate, and their oligomers or copolymers, and beside the foregoing compounds, an etherification product of an oxetane alcohol with a resin having a hydroxyl group such as novolac resin, poly(p-hydroxystyrene), a cardo-type bisphenol compound, a calixarene compound, a calixresorcine arene compound, or silsesquioxane can be used. In addition, mention may be made of a copolymer of an unsaturated monomer having an oxetane ring and an alkyl(meth)acrylate.

As an example of an episulfide resin having at least two thioether groups, mention may be made of YL 7000, a bisphenol A type episulfide resin commercially available from Japan Epoxy Resin Co. Ltd., but examples of available resins are not limited thereto.

Moreover, one can use an episulfide resin wherein the oxygen atom of the epoxy group of the novolac epoxy resin is replaced with a sulfur atom. As a commercially available resin, one can use YDCN-500-80P from Kukdo Chem., Co., Ltd.

The photosensitive resin composition can include the thermosetting binder resin in an amount of 0.5% to 40% by weight, and preferably 5% to 25% by weight. When the content of the thermosetting binder resin is too low, the film may disadvantageously suffer a decrease in heat resistance, alkaline resistance, and an electrical insulation property due to the remaining carboxyl group in the cured film. When the content of the thermosetting binder resin is too high, the film strength may disadvantageously deteriorate since the cyclic (thio)ether having a lower molecular weight is left behind in the dried film.

The photosensitive resin composition according to the embodiments of the present invention as described above can further include some additives as follows.

Thermocuring Catalyst

A thermocuring catalyst as an additive that can be added to the photosensitive resin composition according to the foregoing embodiments plays a role of facilitating the curing of the thermosetting binder resin.

As described above, because the photosensitive resin composition according to an embodiment of the present invention can include a thermosetting binder resin with at least two cyclic thio(ether) groups, it can include a thermocuring catalyst. As examples of the thermocuring catalyst that can be added, mention may be made of an imidazole compound such as imidazole, 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-4-methylimidazole; an amine compound such as dicyandiamide, benzyldimethylamine, 4-(dimethylamino)-N,N-dimethylbenzylamine, 4-methoxy-N,N-dimethylbenzylamine, and 4-methyl-N,N-dimethylbenzylamine; a hydrazide compound such as adiphic dihydrazide and sebaccic dihydrazide; and a triphenylphosphine compound.

In addition, as examples of the commercially available thermocuring catalyst, mention may be made of 2MZ-A, 2MZ-OK, 2PHZ, 2P4BHZ, 2P4 MHZ (all of which are trade names of the imidazole compounds) from Shikoku Kasei Kogyo Co., Ltd., U-CAT3503N and UCAT3502T (both of which are trade names of block isocyanate compounds of dimethylamine) from Sanapro Co., Ltd., and DBU, DBN, U-CATSA102, and U-CAT5002 (all of which are bicyclic amidine compounds and their salts).

However, the examples of the thermocuring catalyst that can be used are not limited to the foregoing ones, and any compound known to be a thermocuring catalyst of the epoxy resin and the oxetane compound or a thermocuring catalyst promoting the reactions between the epoxy group and/or oxetanyl group and the carboxyl group can be used with no limitation.

Moreover, it is possible to use an S-triazine derivative such as guanamine, acetoguanamine, benzoguanamine, melamine, 2,4-diamino-6-methacryloyloxyethyl-S-triazine, 2-vinyl-4,6-diamino-S-triazine, a 2-vinyl-4,6-diamino-S-triazine isocyanuric acid adduct, and a 2,4-diamino-6-methacryloyloxyethyl-S-triazine isocyanuric acid adduct.

The thermocuring catalyst can be used in a proper amount in light of the curing extent of the thermosetting binder resin, and for example, the photosensitive resin composition can include the thermocuring catalyst in an amount of 0.01% to 7% by weight, and preferably 0.1% to 5% by weight.

Thermocuring Agent

The thermocuring agent plays a role of increasing the curing extent of the thermosetting binder resin. Specific examples of the thermocuring agent that can be used include an amine compound, an acid anhydride compound, an amide compound, and a phenol compound. For the amine compound, one can use diaminodiphenyl methane, diethylenetriamine, triethylenetriamine, diaminodiphenyl sulfone, or isophoronediamine. As the acid anhydride compound, one can use phthalic anhydride phthalic, trimellitic anhydride, pyromellitic anhydride, maleic anhydride, tetrahydro phthalic anhydride, methyl tetrahydro phthalic anhydride, methyl nadic anhydride, hexahydro phthalic anhydride, and methyl hexahydro phthalic anhydride. For the amide compound, one can use dicyandiamide and a polyamide resin prepared from a dimer of linoleic acid and ethylene diamine. For the phenol compound, one can use polyhydric phenols such as bisphenol A, bisphenol F, bisphenol S, fluorene bisphenol, and terpene diphenol; a phenol resin prepared from the condensation of phenols and aldehydes, ketones, or dienes; modified products of phenols and/or phenol resins; halogenated phenols such as tetrabromo bisphenol A and brominated phenol resin; and other imidazoles, BF3-amine complexes, and guanidine derivatives.

The thermocuring agent can be used in a proper amount in light of the mechanical properties of the dry film as prepared. For example, the photosensitive resin composition can include the thermocuring agent in an amount of 0.01% to 10% by weight, and preferable 0.1% to 5% by weight.

Filler

The filler takes a role of reinforcing heat resistance, a moisture absorbing property, dimensional stability, and the colors. Further, the filler enhances the heat-resistant stability, the dimensional stability against heat, and the adhesion strength of the resin, and also acts as an extender pigment by reinforcing the colors.

As the filler, one can use any inorganic or organic filler such as barium sulfate, barium titanate, amorphous silica, crystalline silica, fused silica, spherical silica, talc, clay, magnesium carbonate, calcium carbonate, aluminum oxide (alumina), aluminum hydroxide, mica, and the like.

The filler may be used in a suitable amount in light of the mechanical properties of the dry film. For example, the photosensitive resin composition can include the filler in an amount of 0.01% to 20% by weight, and preferably 0.1% to 10% by weight. When its amount is too small, the filler can bring about only an insignificant effect on the enhancement of the heat resistance, the moisture absorbing property, and the dimensional stability therefrom. When its amount is overly large, the filler can cause an increase in the viscosity of the composition, resulting in deterioration of the coating ability or a decrease in the curing extent.

Pigments

The pigment takes a part in hiding defects such as scratches of the circuit lines by providing visibility and a hiding power.

As the pigment, it is possible to use red, blue, green, yellow, and black pigments. For the blue pigment, one can use pigment blue 15:1, pigment blue 15:2, pigment blue 15:3, pigment blue 15:4, pigment blue 15:6, pigment blue 60, and the like. For the green pigment, it is possible to use pigment green 7, pigment green 36, solvent green 3, solvent green 5, solvent green 20, solvent green 28, and the like. As examples of the yellow pigment, mention may be made of an anthraquinone compound, an isoindolinone compound, a condensed azo compound, and a benzimidazolone compound, and for example, one can use pigment yellow 108, pigment yellow 147, pigment yellow 151, pigment yellow 166, pigment yellow 181, pigment yellow 193, and the like.

It is preferred that the content of the pigment ranges from 0.01% to 5% by weight, and preferably from 0.05% to 3% by weight based on the total weight of the photosensitive resin composition.

Using the pigment in an amount of less than 0.01% by weight may cause a decrease in the visibility and the hiding power, while using it in an amount of more than 5% by weight may lead to deterioration of the heat resistance.

Leveling Agent

The leveling agent takes a part in eliminating a bubble or a crater on the surface of the film during a coating process. As the leveling agent, it is possible to use a silicone compound, a fluorine compound, and a polymeric compound, for example BYK-380N, BYK-307, BYK-378, BYK-350, and the like produced by BYK-Chemie GmbH.

The leveling agent can be used in an appropriate amount in light of the surface characteristics of the dry film as prepared. For example, the photosensitive resin composition of the present invention can include the leveling agent in an amount of 0.1% to 20% by weight, and preferably 1% to 10% by weight. Using too small an amount of the leveling agent can have only an insignificant effect on the elimination of the bubble or the crater, while using an overly large amount of the leveling agent may cause a number of bubbles in the film.

Dispersant

Dispersants may be added for the purpose of enhancing the dispersibility of the filler or the pigment. Examples of available dispersants include Disperbyk-110, Disperbyk-162, and Disperbyk-168 from BYK-Chemie GmbH.

One can use the dispersant in an appropriate amount, taking into account the dispersibility of each component. For example, the photosensitive resin composition of the present invention can include the dispersant in an amount of 0.1% to 30% by weight, and preferably 1% to 20% by weight. When the added amount of the dispersant is too small, one cannot expect a sufficient level of dispersion. When an excessively large amount of the dispersant is added, the heat resistance and the reliability may be affected.

Besides the foregoing additives such as the filler, the leveling agent, and the dispersant, the photosensitive resin composition of the present invention can further include well-known additives including a silane coupling agent such as an imidazole-, thiazole-, or triazole-based compound; and/or a flame retardant such as a phosphorous flame retardant or an antimony flame retardant. Further, when such a silane coupling agent and/or flame retardant is added, it can be added in an amount of 0.01% to 30% by weight, and preferably 0.1% to 20% by weight, based on the weight of the photosensitive resin composition.

Solvent

The solvent can be used for the purpose of dissolving the photosensitive resin composition and imparting suitable viscosity for the application of the composition.

As specific examples of the solvent, mention may be made of ketones such as methylethylketone, cyclohexanone, and the like; aromatic hydrocarbons such as toluene, xylene, tetramethylbenzene, and the like; glycol ethers (cellosolves) such as ethylene glycol monoethylether, ethylene glycol monomethylether, ethylene glycol monobutylether, diethylene glycol monoethylether, diethylene glycol monomethylether, diethylene glycol monobutylether, propylene glycol monomethylether, propylene glycol monoethylether, dipropylene glycol diethylether, triethylene glycol monoethylether, and the like; acetic acid esters such as ethyl acetate, butyl acetate, ethylene glycol monoethylether acetate, ethylene glycol monobutylether acetate, diethylene glycol monoethylether acetate, dipropylene glycol monomethylether acetate, and the like; alcohols such as ethanol, propanol, ethylene glycol, propylene glycol, carbitol, and the like; aliphatic hydrocarbons such as octane, decane, and the like; petroleum solvents such as petroleum ether, petroleum naphtha, hydrogenated petroleum naphtha, solvent naphtha, and the like; and amides such as dimethyl acetamide, dimethylformamide (DMF), and the like. The solvent may be used alone or in combination of at least two of them.

The solvent may be used in a proper amount in light of the dispersibility, the solubility, or the viscosity of the photosensitive resin composition. For example, the photosensitive resin composition of the present invention can include the solvent in an amount of 0.1% to 50% by weight, and preferably 1% to 30% by weight. Using too small an amount of the solvent may bring about an increased viscosity, leading to a lowered coating ability. Using an excessively large amount of the solvent may cause difficulties in a solvent drying process, leading to increased tackiness of the film.

According to other embodiments of the present invention, a dry film solder resist prepared by using the photosensitive resin composition as described above is provided.

As stated above, using the photosensitive resin composition including a thioxanthone compound together with the photoinitiator makes it possible to provide a dry film solder resist that is superior in photocuring properties, plating resistance, mechanical properties, and heat resistance.

In particular, when using a mixture of 2-isopropyl thioxanthone and 4-isopropyl thioxanthone, more preferably a mixture of 2-isopropyl thioxanthone and 4-isopropyl thioxanthone at a ratio of 1:2 to 2:1, one can obtain a dry film solder resist with greatly improved initial photocuring characteristics including plating resistance and excellent mechanical properties such as heat resistance and durability.

The dry film solder resist can be obtained by applying the foregoing photosensitive resin composition on a certain substrate and drying the same. Therefore, the dry film solder resist can include a cured or dried product of the photosensitive resin composition as described above.

Specifically, it is possible to obtain a dry film including a carrier film, a photosensitive film, and a release film, all of which are layered in this order, by applying the photosensitive resin composition onto the carrier film such as a PET film, drying the same in a drying apparatus such as an oven, and laminating a release film.

In the application process, one can use any typical method and apparatus known to be available for applying any photosensitive resin composition. For example, one can use a comma coater, a blade coater, a lip coater, a road coater, a squeeze coater, a reverse coater, a transfer roll coater, a gravure coater, a spray coater, and the like.

The thickness of the photosensitive film prepared from the photosensitive resin composition is in a range of 5 μm to 100 μm, and preferably 10 μm to 40 μm.

For the carrier film, it is possible to use any plastic film such as polyethylene terephthalate (PET) film, a polyester film, a polyimide film, a polyamideimide film, a polypropylene film, and a polystyrene film.

For the release film, one can use a polyethylene (PE) film, a polytetrafluoroethylene film, a polypropylene film, a surface-treated paper, and the like.

In this regard, for peeling off the release film, it is preferable that the adhesion between the photosensitive film and the release film is weaker than the adhesion between the photosensitive film and the carrier film.

The drying temperature in the oven can be from 50° C. to 130° C., and preferably 70° C. to 100° C.

The dry film solder resist can be applied to various types of circuit boards. Examples of such circuit boards include, but are not limited to, a printed circuit board (PCB), a semiconductor package substrate, and a flexible printed circuit board (FPCB).

Specifically, the dry film solder resist can be used as a protective film for a printed circuit board.

When the dry film solder resist is actually applied, one can use a method wherein the release film is removed from the surface of the resist, and the photosensitive film layer is vacuum-laminated onto a substrate with a circuit formed thereon. In the vacuum lamination, it is possible to use a vacuum laminator, a hot roll laminator, or a vacuum press for connection therebetween.

A predetermined pattern can be formed by placing a photomask corresponding to the circuit pattern onto the photosensitive film as it is vacuum laminated and subjecting the same to exposure to light. The light source that can be used in the exposure to light includes UV light, an electronic beam, an X-ray, and the like. The exposure to light can be selectively carried out using a photomask or a pattern can be directly formed by irradiation of a laser apparatus. The carrier film is peeled off prior to or after the irradiation. The light intensity depends on the film thickness, but preferably is in a range of 0 to 1000 mJ/cm².

After the exposure to light, developing the photosensitive film eliminates unnecessary portions thereof to produce a desired pattern. As a developing solution, it is possible to use an aqueous solution of an alkaline compound such as potassium hydroxide, sodium hydroxide, sodium carbonate, potassium carbonate, sodium phosphate, sodium silicate, ammonia, and an amine compound. After being developed with the aqueous alkaline solution, the film is washed with water.

After the developing and the washing processes, the film is heated and cured in an oven at a temperature of 140° C. to 160° C. for 0.5 to 2 hours, and is finally photocured (i.e., post-cured) at a light intensity of 500 to 2000 mJ/cm² to provide a printed circuit board including the dry film solder resist.

According to other embodiments of the present invention, a circuit board including the dry film solder resist is also provided.

As described above, the dry film solder resist can be used as a protective film for a circuit board, examples of which include a printed circuit board (PCB), a semiconductor package substrate, and a flexible printed circuit board (FPCB).

### Advantageous Effect of the Invention

According to the present invention, a photosensitive resin composition and a dry film solder resist that are capable of providing a photosensitive material that is superior in photocuring characteristics, plating resistance, mechanical properties, and heat resistance, and a circuit board including the dry film solder resist, are provided.

### DETAILED EMBODIMENTS OF THE INVENTION

Hereinafter, the actions and the effects of the present invention will be explained in more detail via specific examples of the invention. However, these examples are merely illustrative of the present invention and the scope of the invention should not be construed to be defined thereby.

### EXAMPLE

### Example 1

(1) Preparation of the Photosensitive Resin Composition

40% by weight of CCR-1235 from Nippon Kayaku, Co., Ltd. as an acid modified oligomer, 10% by weight of DPEA-12 from Kayarad as a photopolymerizable monomer, 4% by weight of TPO as a photoinitiator, 1% by weight of ITX (a mixture of 2-isopropyl thioxanthone and 4-isopropyl thioxanthone at a mole ratio of 1:1), 15% by weight of EOCN-1020 from Nippon Kayaku Co., Ltd. as an epoxy resin, 0.1% by weight of dicyanamide as an epoxy curing agent, 0.1% by weight of 2Ml as an epoxy catalyst, 15% by weight of BaSO₄ as a filler, 0.2% by weight of Pigment Blue 15:3 and 0.2% by weight of Pigment Yellow 151 as a pigment, 0.3% by weight of BYK-380N as a leveling agent, 0.1% by weight of Disperbyk-110 as a dispersant, and 14% by weight of DMF as a solvent were mixed to provide a photosensitive resin composition.

(2) Preparation of a Dry Film

The photosensitive resin composition prepared as above was applied onto a PET film as a carrier film, and subsequently the resulting assembly was passed through an oven at 75° C. and then laminated with a PE film as a release film to provide a dry film composed of the carrier film, the photosensitive film (having a thickness of 20 μm), and the release film, all of which were layered in this order.

(3) Preparation of a Protective Film for a Printed Circuit Board and a Printed Circuit Board Including the Same

After its cover film was peeled off, the photosensitive film layer of the dry film as prepared was vacuum-laminated onto a substrate with a circuit formed thereon and a photomask corresponding to the circuit pattern was placed onto the photosensitive film, which was then exposed to a UV ray.

Then, the irradiated film was developed with an alkaline solution to remove the unnecessary portions and form a desired pattern. The patterned film was then photocured to provide a printed circuit board including a protective film (a solder resist) formed from the photosensitive film.

### Example 2

Except that 4% by weight of 1651 was used for a photoinitiator and 1% by weight of ITX was used, a photosensitive resin composition was prepared in the same manner as set forth in Example 1, and then a printed circuit board was prepared in the same manner as set forth in Example 1.

### Example 3

Except that 3.5% by weight of TPO was used for a photoinitiator and 1.5% by weight of ITX was used, a photosensitive resin composition was prepared in the same manner as set forth in Example 1, and then a printed circuit board was prepared in the same manner as set forth in Example 1.

### COMPARATIVE EXAMPLE

### Comparative Example 1

Except that 5% by weight of TPO was used alone instead of 4% by weight of TPO and 1% by weight of ITX, a photosensitive resin composition was prepared in the same manner as set forth in Example 1, and then a printed circuit board was prepared in the same manner as set forth in Example 1.

### Comparative Example 2

Except that 5% by weight of 1819 was used alone instead of 4% by weight of TPO and 1% by weight of ITX, a photosensitive resin composition was prepared in the same manner as set forth in Example 1, and a printed circuit board was prepared in the same manner as set forth in Example 1.

### Comparative Example 3

Except that 5% by weight of 1369 was used alone instead of 4% by weight of TPO and 1% by weight of ITX, a photosensitive resin composition was prepared in the same manner as set forth in Example 1, and then a printed circuit board was prepared in the same manner as set forth in Example 1.

### Comparative Example 4

Except that 5% by weight of 1651 was used alone instead of 4% by weight of TPO and 1% by weight of ITX, a photosensitive resin composition was prepared in the same manner as set forth in Example 1, and then a printed circuit board was prepared in the same manner as set forth in Example 1.

### Test Example

### Evaluation of Properties of the Protective Film for a Printed Circuit Board

With respect to the protective films for a printed circuit board as prepared in Examples 1 to 3 and Comparative Examples 1 to 4, plating resistance and heat resistance reliability were evaluated. The results are shown in the following Table 1. The protective films for a printed circuit board for each of the examples and comparative examples were obtained by irradiation at a light intensity of 250 mJ/cm² and 550 mJ/cm².

### Experimental Example 1

### A Method of Measuring Plating Resistance

After being subjected to an electroless nickel immersion gold (ENIG) process, the printed circuit boards were examined with regard to whether they had any whitening or discolored or peeled portion.

### Experimental Example 2

### Method of Measuring Heat Resistance Reliability

The protective film for a printed circuit board was laminated onto a CCL and was then subjected to photocuring, thermal curing, and post-photocuring. The resulting product was cut in a size of 150 mm×130 mm. A lead bath (i.e., an electrical furnace that is electrically heated, has a temperature-control ability, and includes at least 2.25 kg of lead for a test) was set at a temperature of 288° C. and the test sample was made to float in the lead bath with its film side facing upward. The appearance of the test sample was examined to find out whether the film was peeled or deformed.

TABLE 1
Results of Experimental Examples 1 and 2

| | Plating | | Heat | Heat |
|---|---|---|---|---|
| | resistance | Plating | resistance | resistance |
| | (250 mJ/ | resistance | reliability | reliability |
| | cm²) | (550 mJ/cm²) | (250 mJ/cm²) | (550 mJ/cm²) |
| Example 1 | OK | OK | OK | OK |
| Example 2 | OK | OK | OK | OK |
| Example 3 | OK | OK | OK | OK |
| Comp. | NG | OK | NG | OK |
| Example 1 | | | | |
| Comp. | NG | OK | NG | OK |
| Example 2 | | | | |
| Comp. | NG | OK | NG | OK |
| Example 3 | | | | |
| Comp. | NG | NG | NG | NG |
| Example 4 | | | | |

Plating resistance: NG - whitening observed, OK - no whitening
Heat resistance reliability: NG - bursting at 288° C. solder floating, OK - no bursting at 288° C. solder floating

Table 1 shows that the films prepared by adding ITX were able to secure plating resistance and heat resistance reliability not only at a light intensity of 550 mJ/cm² but also at a light intensity of 250 mJ/cm². Further, comparison between the results of Comparative Example 4 and Example 1 reveals that the composition prepared by using 1651 alone as a photoinitiator failed to assure the plating resistance and the heat resistance reliability even for the film obtained by irradiation at a light intensity of 550 mJ/cm², but when ITX was added to such a composition, even the film obtained by irradiation at a light intensity of 250 mJ/cm² exhibited the plating resistance and heat resistance reliability.

Except for Comparative Example 4, the films as prepared without any ITX added showed good results for the plating resistance and the heat resistance reliability when being prepared by irradiation at a light intensity of 550 mJ/cm². However, they showed inferior plating resistance when being prepared by irradiation at a light intensity of 250 mJ/cm².

What is claimed is:

1. A photosensitive resin composition comprising an acid modified oligomer, a photopolymerizable monomer, a thermosetting binder resin, a photoinitiator, and a thioxanthone compound.

2. The photosensitive resin composition according to claim 1, wherein the thioxanthone compound comprises a compound of Chemical Formula 1: 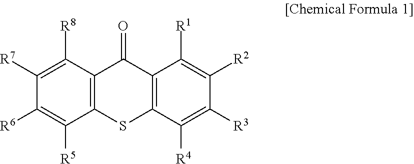
wherein each of R¹ to R⁸ can be the same as or different from one another, and are hydrogen, a C1 to C5 alkyl, a C1 to C5 alkylene, or a C1 to C5 alkenyl.

3. The photosensitive resin composition according to claim 1, wherein the thioxanthone compound comprises at least one selected from the group consisting of 2-isopropyl thioxanthone and 4-isopropyl thioxanthone.

4. The photosensitive resin composition according to claim 1, wherein the thioxanthone compound is a mixture of 2-isopropyl thioxanthone and 4-isopropyl thioxanthone at a ratio of 1:2 to 2:1.

5. The photosensitive resin composition according to claim 1, wherein the acid modified oligomer comprises an oligomer with a carboxyl group and a vinyl group substituted therewith.

6. The photosensitive resin composition according to claim 1, wherein the acid modified oligomer has an acid value of 40 to 120 mg KOH/g.

7. The photosensitive resin composition according to claim 1, wherein the photopolymerizable monomer comprises a multifunctional compound with at least two vinyl groups.

8. The photosensitive resin composition according to claim 1, wherein the photopolymerizable monomer comprises a multifunctional (meth)acrylate compound with at least two (meth)acryloyl groups in a molecule.

9. The photosensitive resin composition according to claim 1, wherein the photoinitiator comprises at least one selected from the group consisting of a benzoin compound, an acetophenone compound, an anthraquinone compound, a thioxanthone compound, a ketal compound, a benzophenone compound, an α-aminoacetophenone compound, an acylphosphine oxide compound, an oxime ester compound, a biimidazole compound, and a triazine compound.

10. The photosensitive resin composition according to claim 1, wherein the thermosetting binder resin is a thermosetting resin comprising at least one functional group selected from the group consisting of an epoxy group, an oxetanyl group, a cyclic ether group, and a cyclic thioether group.

11. The photosensitive resin composition according to claim 1, wherein the thermosetting binder resin comprises at least one resin selected from the group consisting of a multifunctional epoxy resin having at least two epoxy groups, a multifunctional oxetane resin having at least two oxetanyl groups, and a multifunctional episulfide resin having at least two thioether groups.

12. The photosensitive resin composition according to claim 1, comprising:
15% to 75% by weight of the acid modified oligomer;
5% to 40% by weight of the photopolymerizable monomer;
0.5% to 40% by weight of the thermosetting binder resin; and
1% to 20% by weight of the photoinitiator and the thioxanthone compound.

13. The photosensitive resin composition according to claim 1, comprising 3 to 70 parts by weight of the thioxanthone compound with respect to 100 parts by weight of the photoinitiator.

14. The photosensitive resin composition according to claim 1, further comprising a thermocuring catalyst, a thermocuring agent, a filler, a pigment, a leveling agent, a dispersant, or a solvent.

15. A dry film solder resist prepared by using a photosensitive resin composition of claim 1.

16. The dry film solder resist according to claim 15, comprising a cured product or a dried product of the photosensitive resin composition.

17. The dry film solder resist according to claim 15, wherein it is used for a protective film for a printed circuit board.

18. A circuit board comprising the dry film solder resist of claim 17.
